(19) United States
(12) Patent Application Publication
(10) Pub. No.: US 2025/0056850 A1
(43) Pub. Date: Feb. 13, 2025

(54) NANOWIRE/NANOSHEET DEVICE WITH CRYSTAL SPACER AND METHOD OF MANUFACTURING THE SAME, AND ELECTRONIC APPARATUS

(71) Applicant: INSTITUTE OF MICROELECTRONICS, CHINESE ACADEMY OF SCIENCES, Beijing (CN)

(72) Inventor: Huilong ZHU, Poughkeepsie, NY (US)

(21) Appl. No.: 18/719,156

(22) PCT Filed: Feb. 17, 2022
(86) PCT No.: PCT/CN2022/076636

§ 371 Date: Jun. 12, 2024

(30) Foreign Application Priority Data
Dec. 13, 2021 (CN) 202111521276.0

(51) Int. Cl. H01L 29/06; H01L 21/762; H01L 21/8234; H01L 27/088; H01L 29/08; H01L 29/423; H01L 29/66; H01L 29/775; H01L 29/786

(52) U.S. Cl. CPC H01L 29/0673; H01L 21/76224; H01L 21/823412; H01L 21/823418; H01L 21/823468; H01L 21/823481; H01L 27/088; H01L 29/0847; H01L 29/42392; H01L 29/66439; H01L 29/66545; H01L 29/775; H01L 29/78696

(57) ABSTRACT

A nanowire/nanosheet device with a crystal spacer, a method of manufacturing the nanowire/nanosheet device with the crystal spacer, and an electronic apparatus including the nanowire/nanosheet device are provided. The nanowire/nanosheet device includes: a substrate; a nanowire/nanosheet spaced apart from a surface of the substrate and extending in a first direction; source/drain layers located at opposite ends of the nanowire/nanosheet in the first direction and adjoining the nanowire/nanosheet; a gate stack extending in a second direction intersecting with the first direction to surround the nanowire/nanosheet; and a spacer provided on a sidewall of the gate stack, wherein the spacer has a crystal structure substantially identical to a crystal structure of the nanowire/nanosheet in at least a part of a region of the spacer adjacent to the nanowire/nanosheet.

### CROSS REFERENCE TO RELATED APPLICATION(S)

This application is a Section 371 National Stage Application of International Application No. PCT/CN2022/076636, filed on Feb. 17, 2022, and entitled “NANOWIRE/NANOSHEET DEVICE WITH CRYSTAL SPACER AND METHOD OF MANUFACTURING THE SAME, AND ELECTRONIC APPARATUS”, which claims priority to Chinese Patent Application No. 202111521276.0, filed on Dec. 13, 2021 and entitled “NANOWIRE/NANOSHEET DEVICE WITH CRYSTAL SPACER AND METHOD OF MANUFACTURING THE SAME, AND ELECTRONIC APPARATUS”, the entire content of which is incorporated herein in its entirety by reference.

### TECHNICAL FIELD

The present disclosure relates to a field of semiconductors, and in particular to, a nanowire/nanosheet device with a crystal spacer, a method of manufacturing the nanowire/nanosheet device with the crystal spacer, and an electronic apparatus including the nanowire/nanosheet device.

### BACKGROUND

A nanowire or nanosheet (hereinafter referred to as “nanowire/nanosheet”) device, especially a Gate-All-Around (GAA) metal oxide semiconductor field effect transistor (MOSFET) based on the nanowire/nanosheet, may effectively control a short channel effect and achieve a further miniaturization of the device. In addition, it is desired to achieve an epitaxial growth of a source/drain for, such as increasing the source/drain to facilitate a fabrication of a contact portion to the source/drain, or achieving stress engineering. However, with continuous miniaturization, it is difficult to grow a high-quality source/drain.

### SUMMARY

In view of above, the object of the present disclosure is at least partially to provide a nanowire/nanosheet device with a crystal spacer, a method of manufacturing the nanowire/nanosheet device, and an electronic apparatus including the nanowire/nanosheet device.

According to an aspect of the present disclosure, a nanowire/nanosheet device is provided, including: a substrate; a nanowire/nanosheet spaced apart from a surface of the substrate and extending in a first direction; source/drain layers located at opposite ends of the nanowire/nanosheet in the first direction and adjoining the nanowire/nanosheet; a gate stack extending in a second direction intersecting with the first direction to surround the nanowire/nanosheet; and a spacer provided on a sidewall of the gate stack, wherein the spacer has a crystal structure substantially identical to a crystal structure of the nanowire/nanosheet in at least a part of a region of the spacer adjacent to the nanowire/nanosheet.

According to another aspect of the present disclosure, a method of manufacturing a nanowire/nanosheet device is provided, including: providing, on a substrate, a nanowire/nanosheet spaced apart from a surface of the substrate and extending in a first direction; forming, on the substrate, a dummy gate extending in a second direction intersecting with the first direction and surrounding the nanowire/nanosheet; forming a spacer on a sidewall of the dummy gate, wherein the spacer has a crystal structure substantially identical to a crystal structure of the nanowire/nanosheet in at least a part of a region of the spacer adjacent to the nanowire/nanosheet; growing a source/drain layer by using an end of the nanowire/nanosheet in the first direction and the at least the part of the region of the spacer as seeds.

According to another aspect of the present disclosure, an electronic apparatus including the nanowire/nanosheet device described above is provided.

### BRIEF DESCRIPTION OF THE DRAWINGS

The above and other objects, features, and advantages of the present disclosure will become more clear through following description on embodiments of the present disclosure with reference to accompanying drawings, in which:

FIGS. 1 to 15(b) show schematic diagrams of some stages in a process of manufacturing a nanowire/nanosheet device according to an embodiment of the present disclosure;

FIGS. 16(a) to 21 show schematic diagrams of some stages in a process of manufacturing a nanowire/nanosheet device according to another embodiment of the present disclosure;

FIGS. 22(a) to 29 show schematic diagrams of some stages in a process of manufacturing a nanowire/nanosheet device according to another embodiment of the present disclosure;

FIG. 30 shows a schematic diagram of a nanowire/nanosheet device according to another embodiment of the present disclosure, wherein FIGS. 1, 3(a), 4(a), 5(b), 6, 7, 8(a), 9(a), 9(b), 10(a), 10(c), 11(a), 12(a), 13(a), 14(a), 15(a), 16(b), 17(b), 18, 19, 20(a), 21, 22(b), 23(b), 24(a), and 25 to 30 are cross-sectional views taken along line AA′,

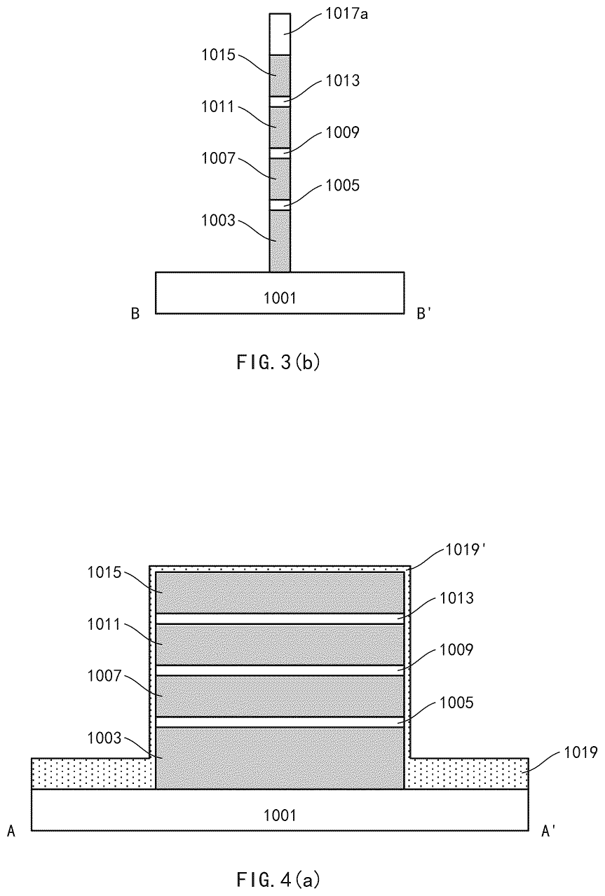

FIGS. 3(b), 4(b), 8(b), 10(b), 11(b), 12(b), 13(b), 14(b), 15(b), 20(b), and 24(b) are cross-sectional views taken along line BB′,

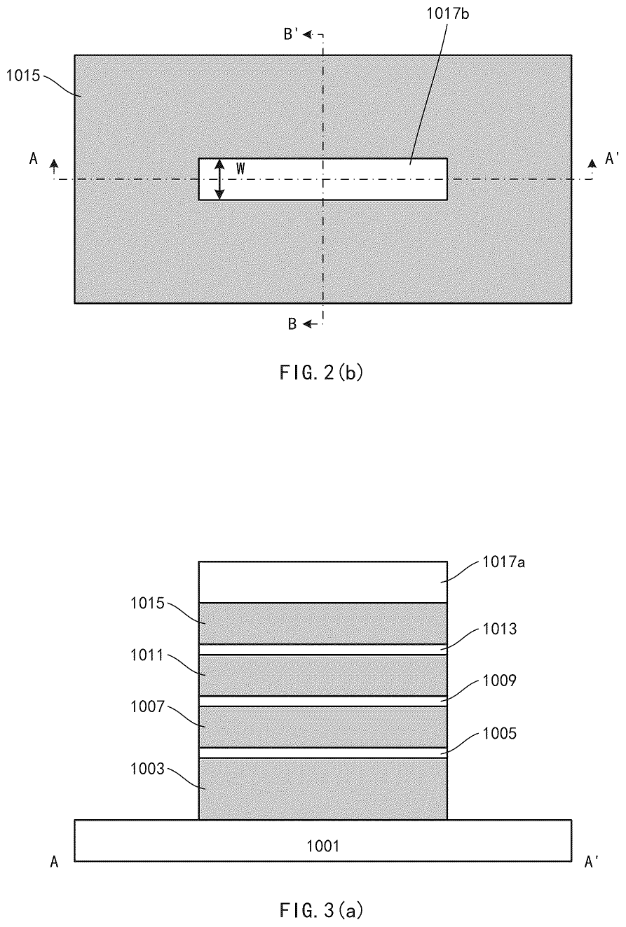

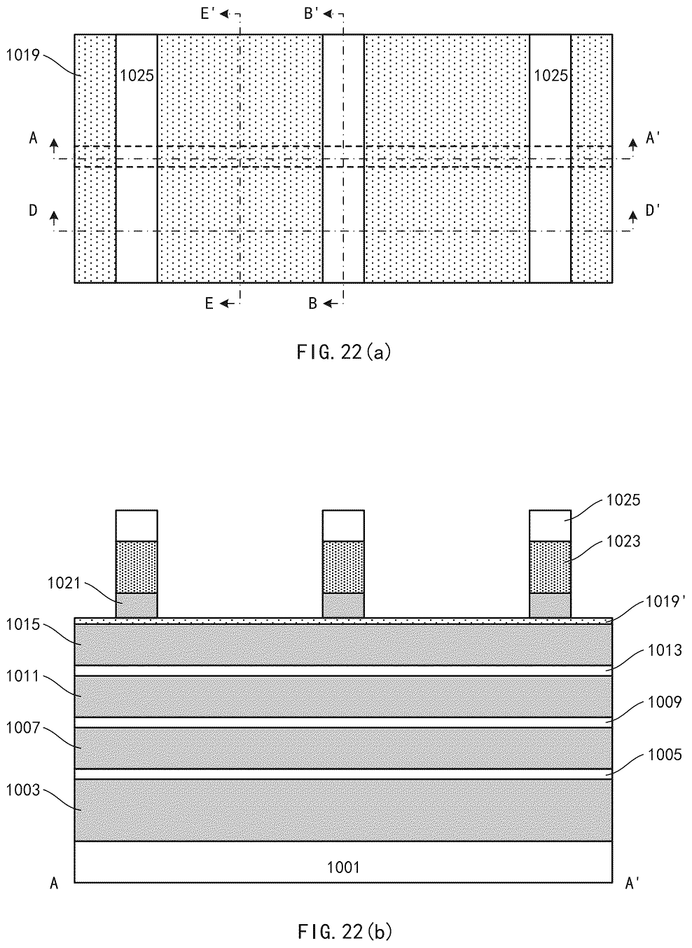

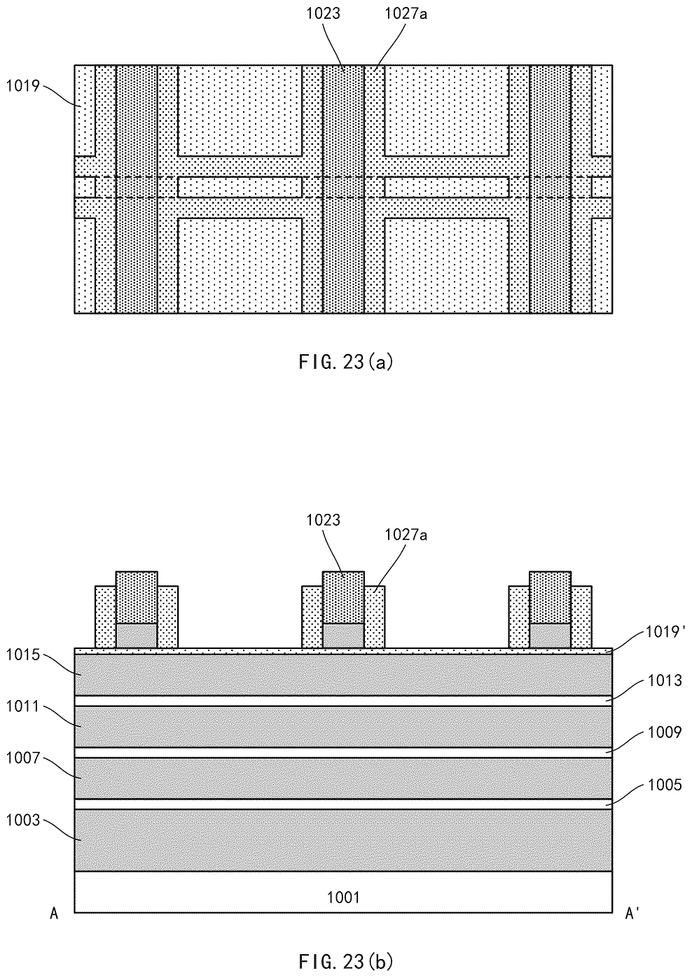

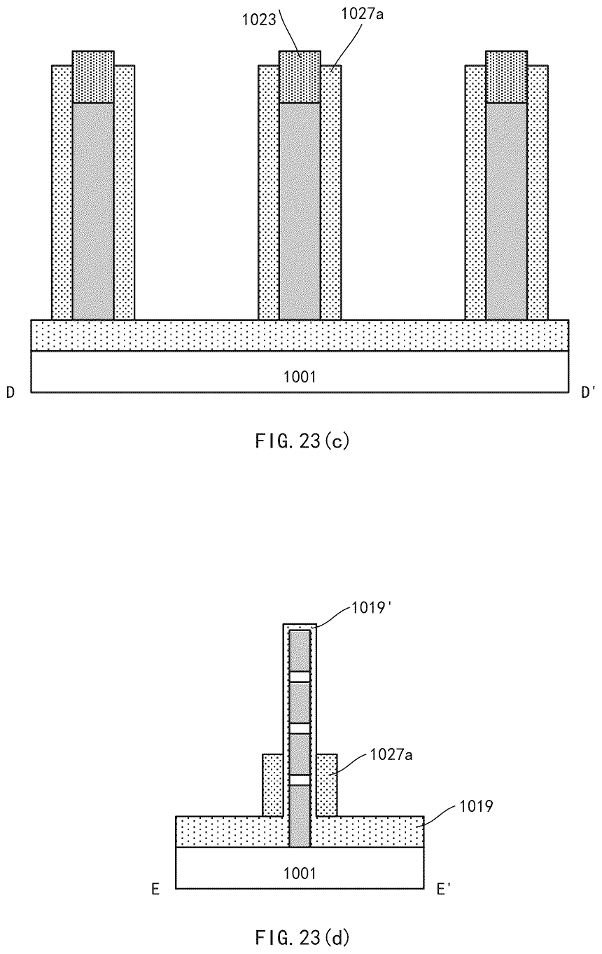

FIGS. 2(a), 2(b), 5(a), 16(a), 17(a), 22(a), and 23(a) are top views, wherein FIG. 2(a) shows positions of line AA′ and line BB′, and FIG. 22(a) shows positions of line DD′ and line EE′, FIG. 23(c) is a cross-sectional view taken along line DD′,

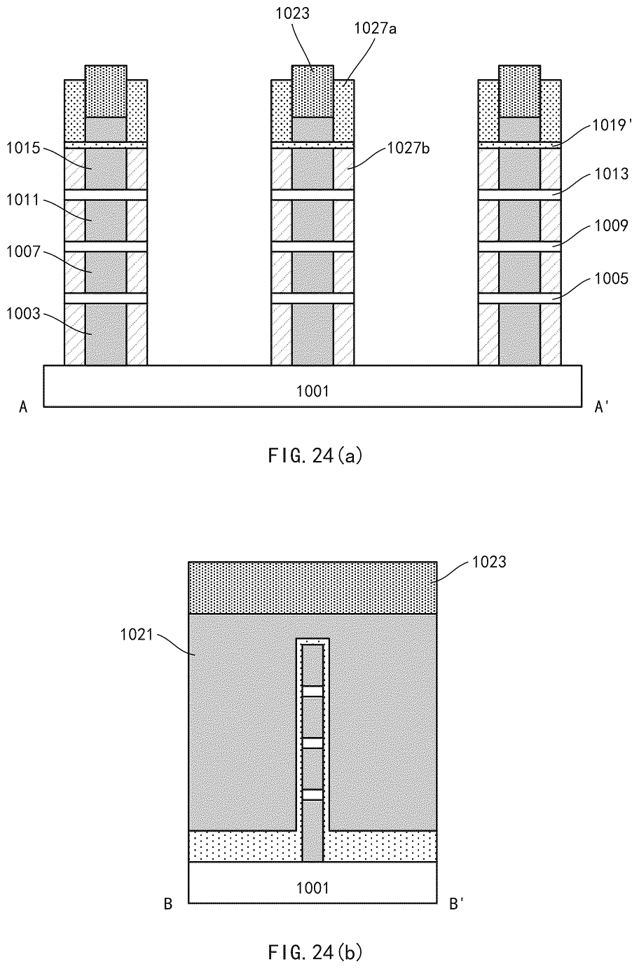

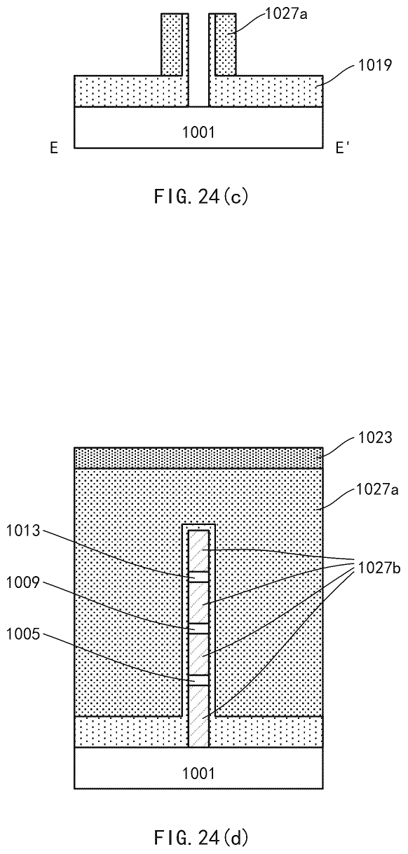

FIGS. 23(d) and 24(c) are cross-sectional views taken along line EE′,

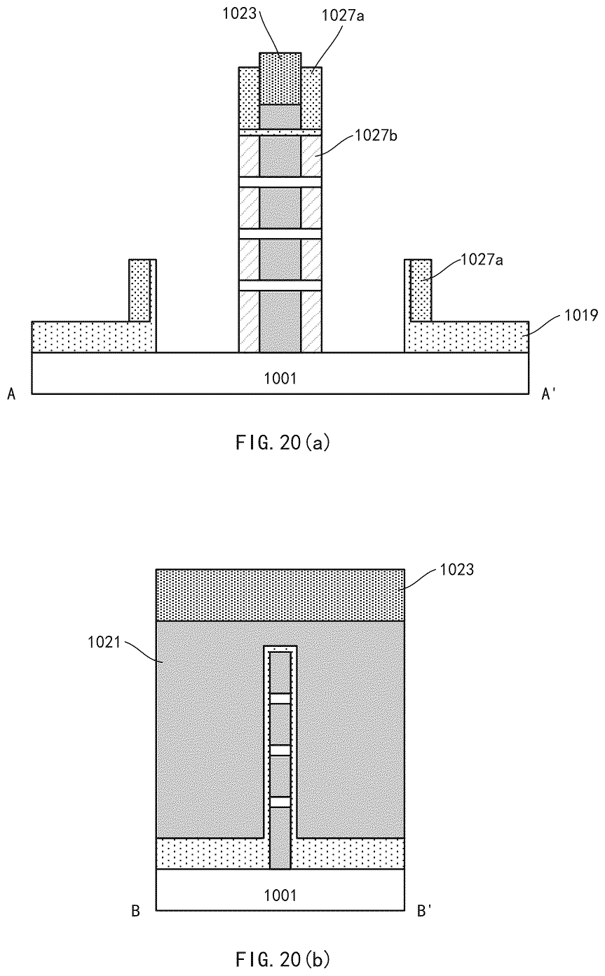

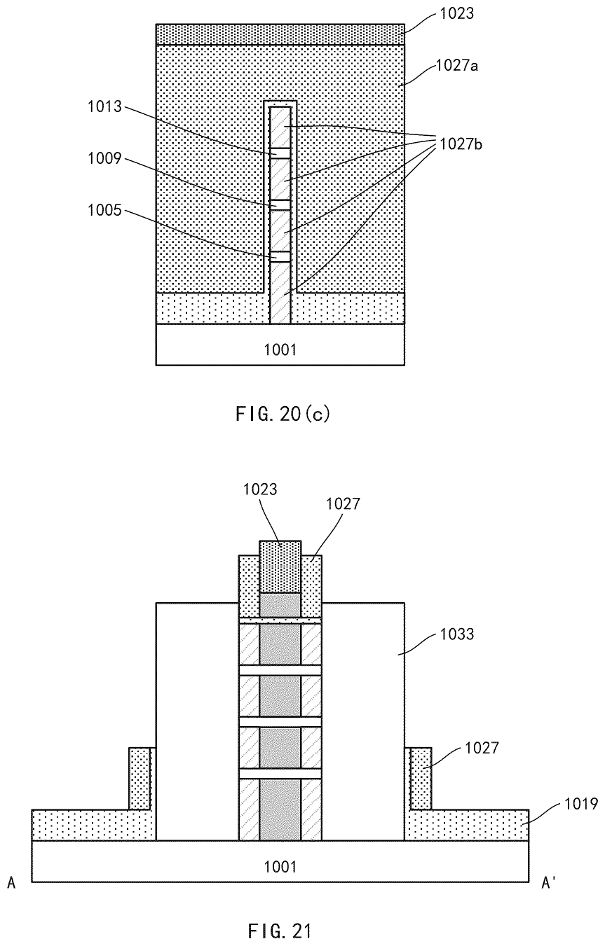

FIGS. 20(c) and 24(d) are cross-sectional views obtained along a sidewall of a spacer.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to the embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice. In the context of the present disclosure, when a layer/element is recited as being “on” a further layer/element, the layer/element may be provided directly on the further layer/element, or otherwise there may be an intervening layer/element interposed therebetween. Further, if a layer/element is “on” a further layer/element in an orientation, then the layer/element may be “under” the further layer/element when the orientation is turned.

According to an embodiment of the present disclosure, a nanowire/nanosheet device is provided. Specifically, the device may include one or more nanowires or nanosheets to serve as a channel. The nanowire/nanosheet may be suspended relative to a substrate and may extend substantially parallel to a surface of the substrate. The nanowires/nanosheets are aligned with each other in a vertical direction (e.g., a direction substantially perpendicular to the surface of the substrate). The nanowire/nanosheet may extend in a first direction, and opposite ends of the nanowire/nanosheet in the first direction may be connected to source/drain layers. The source/drain layer may include a semiconductor material that is different from that of the nanowire/nanosheet to achieve stress engineering. In addition, a gate stack may extend in a second direction intersecting with (such as, perpendicular to) the first direction to intersect with each nanowire/nanosheet, and thus may surround a periphery of each nanowire/nanosheet, so as to form a Gate-All-Around (GAA) structure.

A spacer may be formed on the sidewall of the gate stack. The spacer isolates the gate stack from the source/drain layer. The spacer may have a crystal structure substantially identical to that of the nanowire/nanosheet in at least a part of a region (especially the region of the spacer adjacent to the nanowire/nanosheet). As described below, this helps to improve the crystal quality of the source/drain layer. The spacer may include a dielectric material, such as a low k dielectric material. Alternatively, the spacer may also include a semiconductor material, and a bandgap width of the semiconductor material may be greater than or equal to a bandgap width of the nanowire/nanosheet or a bandgap width of the source/drain layer, thereby performing a function substantially equivalent to a dielectric spacer in terms of electricity.

An isolation portion may be provided between the gate stack and the substrate. The isolation portion may be self-aligned with the gate stack and may be substantially aligned with the nanowire/nanosheet in the vertical direction.

Such semiconductor device may be manufactured as follows. A nanowire/nanosheet, which is spaced apart from a surface of the substrate and extends in the first direction, may be provided on the substrate. A dummy gate, which extends in a second direction intersecting with (such as perpendicular to) the first direction, may be formed to surround the nanowire/nanosheet. A spacer may be formed on a sidewall of the dummy gate. The spacer may have a crystal structure substantially identical to that of the nanowire/nanosheet in at least a part of the region (especially a region of the spacer adjacent to the nanowire/nanosheet). The end of the nanowire/nanosheet in the first direction and (at least the part of the region of) the spacer may be used as seeds to grow the source/drain layer. Compared to growing solely from the end of the nanowire/nanosheet in the first direction as a seed, the source/drain layer may have fewer growth defects, or even substantially no defects, thereby improving the crystal quality of the source/drain layer.

An isolation portion defining layer may be provided on the substrate. The nanowire/nanosheet may be provided on the isolation portion defining layer. The isolation portion defining layer may be patterned in a shape self-aligned with the nanowire/nanosheet, which may be achieved by etching the isolation portion defining layer using the nanowire/nanosheet (or the (hard) mask used to form the nanowire/nanosheet) as a mask. Afterwards, a self-aligned isolation portion may be formed by replacing the isolation portion defining layer with a dielectric material.

In order to provide the nanowire/nanosheet, a stack of alternatively arranged one or more gate defining layers and one or more nanowire/nanosheet defining layers may be formed on the isolation portion defining layer. The stack may be patterned as a preparatory nanowire/nanosheet extending in the first direction. A length of the preparatory nanowire/nanosheet in the first direction may be greater than a length of a resultant nanowire/nanosheet to be formed in the first direction, so as to subsequently form a nanowire/nanosheet self-aligned with the dummy gate. In this patterning step, the isolation portion defining layer may also be patterned. Therefore, the isolation portion defining layer may be self-aligned with the preparatory nanowire/nanosheet. At this point, the gate defining layer is also in a shape of nanowire/nanosheet. To form the GAA, a further gate defining layer may be formed and patterned as a strip extending in the second direction. The further gate defining layer in the strip shape may be used as a mask to pattern the preparatory nanowire/nanosheet below. Therefore, the further gate defining layer in the strip shape forms the dummy gate extending in the second direction along with other gate defining layers. The nanowire/nanosheet defining layer is patterned as a nanowire/nanosheet self-aligned with the dummy gate, and the nanowire/nanosheet is surrounded by the dummy gate. In this patterning step, the isolation portion defining layer may also be patterned. Therefore, the isolation portion defining layer may be self-aligned with the nanowire/nanosheet.

To form a self-aligned spacer, selective etching may be performed on the dummy gate, so that the sidewall of the dummy gate may be inwardly recessed relative to the sidewall of the nanowire/nanosheet to form a recess, and the spacer may be formed in the recess.

The present disclosure may be presented in various forms, some examples of which will be described below. In the following description, a selection of various materials is involved. In the selection of materials, in addition to a function of the material (for example, a semiconductor material may be used to form an active region, a dielectric material may be used to form an electrical isolation), the etching selectivity is also considered. In the following description, the required etching selectivity may or may not be indicated. It should be clear to those skilled in the art that when etching a material layer is described below, if it is not described or shown that other layers are also etched, then the etching may be selective, and the material layer may have an etching selectivity relative to other layers exposed to the same etching recipe.

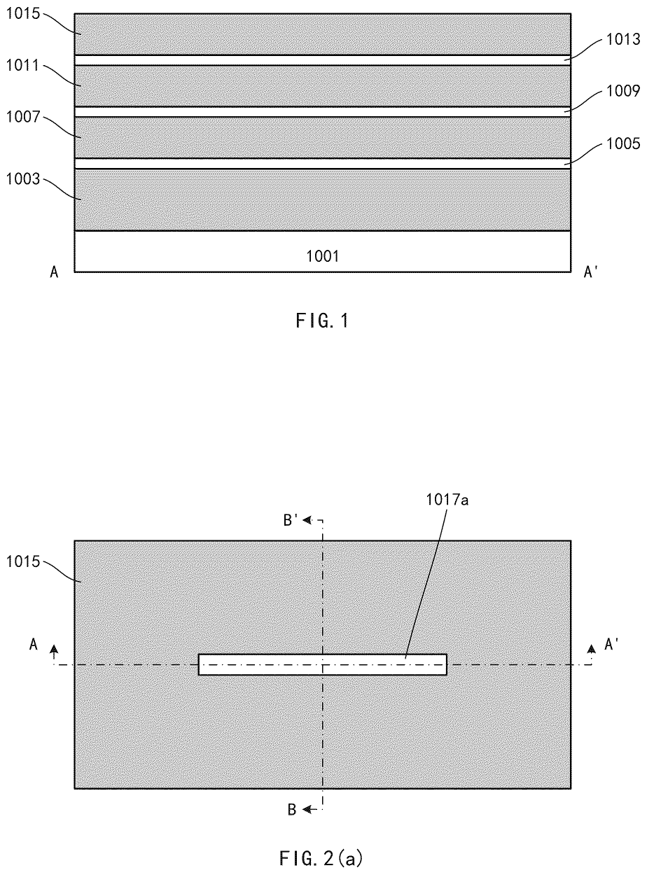

FIGS. 1 to 15(b) show schematic diagrams of some stages in a process of manufacturing a nanowire/nanosheet device according to an embodiment of the present disclosure.

As shown in FIG. 1, a substrate 1001 is provided. The substrate 1001 may be a substrate in various forms, including but not limited to, a bulk semiconductor material substrate such as a bulk Si substrate, a Semiconductor On Insulator (SOI) substrate, a compound semiconductor substrate such as an SiGe substrate, or the like. Hereinafter, the bulk Si substrate will be described by way of example for the convenience of description. Here, a silicon wafer is provided as the substrate 1001.

An isolation portion defining layer 1003 may be formed on the substrate 1001 to define a position of an isolation portion to be formed subsequently. An etch stop layer 1005 may be formed on the isolation portion defining layer 1003. The etch stop layer 1005 may be used to define a stop position when etching the isolation portion defining layer 1003, especially in a case where there is no etching selectivity or low etching selectivity between the isolation portion defining layer 1003 and a gate defining layer (such as 1007) formed subsequently. Alternatively, the etch stop layer 1005 may be omitted in a case where there is an etching selectivity between the isolation portion defining layer 1003 and the gate defining layer formed subsequently.

A stack of alternately arranged gate defining layers 1007, 1011 and 1015 as well as nanowire/nanosheet defining layers 1009 and 1013 may be formed on the etch stop layer 1005. The gate defining layers 1007, 1011 and 1015 may define a position of the gate stack to be formed subsequently. The nanowire/nanosheet defining layers 1009 and 1013 may define a position of the nanowire/nanosheet to be formed subsequently. In this stack, the top layer may be the gate defining layer 1015, so that each nanowire/nanosheet defining layer 1009 or 1013 is covered by the gate defining layers above and below, so as to subsequently form the GAA configuration. In this example, two nanowire/nanosheet defining layers 1009 and 1013 are formed, and thus two nanowires/nanosheets are formed in the resultant device. However, the present disclosure is not limited to this. The number of nanowire/nanosheet defining layers to be formed and the corresponding number of gate defining layers to be formed may be determined according to the number of resultant nanowires/nanosheets to be formed (which may be one or more).

The isolation portion defining layer 1003, the etch stop layer 1005, the gate defining layers 1007, 1011 and 1015, as well as the nanowire/nanosheet defining layers 1009 and 1013 may be semiconductor layers formed on the substrate 1001 by, for example, epitaxial growth. Therefore, the nanowire/nanosheet defining layers 1009 and 1013 may have good crystal quality and may be single crystal structures, so as to subsequently provide single crystal nanowires/nanosheets to serve as channels. Adjacent semiconductor layers among these semiconductor layers may have etching selectivity relative to each other, so that they may be subsequently processed differently. For example, the etch stop layer 1005 and the nanowire/nanosheet defining layers 1009 and 1013 may include Si, while the isolation portion defining layer 1003 and the gate defining layers 1007, 1011, and 1015 may include SiGe (an atomic percentage of Ge is in a range of about 10% to 40%, and may gradually change to reduce defects). Each semiconductor layer may have a substantially uniform thickness, so as to extend substantially parallel to the surface of the substrate 1001. For example, a thickness of the isolation portion defining layer 1003 may be in a range of about 30 nm to 80 nm, a thickness of the etch stop layer 1005 may be in a range of about 3 nm to 15 nm, a thickness of each of the gate defining layers 1007, 1011, and 1015 may be in a range of about 20 nm to 40 nm, and a thickness of each of the nanowire/nanosheet defining layers 1009 and 1013 may be in a range of about 5 nm to 15 nm.

Next, the nanowire/nanosheet may be patterned. For example, as shown in FIG. 2(a) or 2(b), a photoresist 1017a or 1017b may be formed on the above-described stack and patterned in a form of nanowire (FIG. 2(a)) or nanosheet (FIG. 2(b)) through photolithography. In a case of the nanosheet, a width W of the nanosheet may determine a device width for providing a current. In the following descriptions, a case of the nanowire is mainly used as an example, but these descriptions also apply to the case of the nanosheet. Then, as shown in FIGS. 3(a) and 3(b), by using the photoresist 1017a or 1017 as an etching mask, the layers on the substrate 1001 may be selectively etched sequentially by reactive ion etching (RIE) in the vertical direction, and the etching may be stopped at the substrate 1001. In this way, each layer on the substrate 1001 is patterned as a preparatory nanowire or nanosheet corresponding to the photoresist 1017a or 1017b. Here, a length of the preparatory nanowire/nanosheet (a longitudinal scale, i.e., a length of the preparatory nanowire/nanosheet in a horizontal direction of the paper plane under an orientation in FIG. 3(a)) may be greater than the length of the nanowire/nanosheet to be formed as the channel, so as to subsequently obtain the nanowire/nanosheet self-aligned with the dummy gate (gate stack) to serve as the channel. Afterwards, the photoresist 1017a or 1017b may be removed.

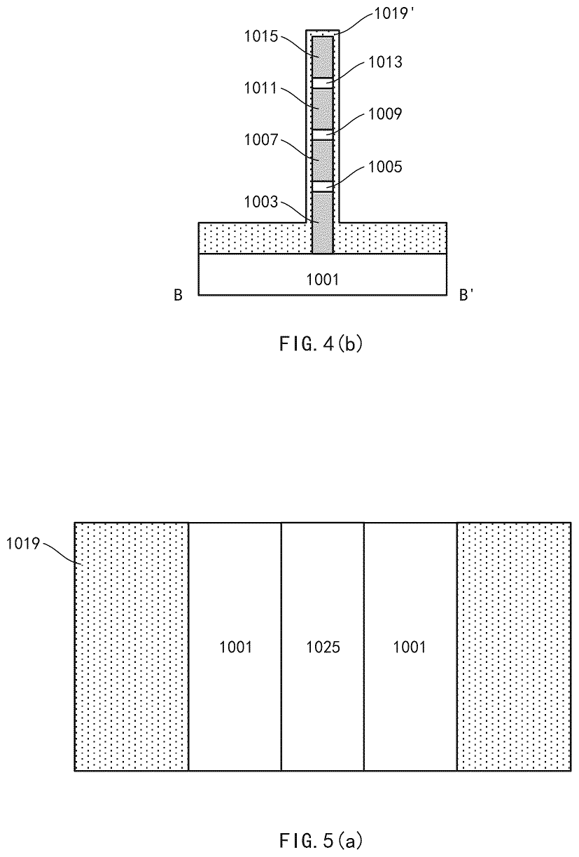

For the purpose of electrical isolation, as shown in FIGS. 4(a) and 4(b), an isolation portion 1019 may be formed on the substrate 1001, such as shallow trench isolation (STI). For example, an STI 1019 may be formed by depositing an oxide (such as a silicon oxide) on the substrate, performing a planarization processing such as chemical mechanical polishing (CMP) on the deposited oxide, and etching back the planarized oxide through wet etching or vapor or dry etching. In addition, a thin etch stop layer 1019′ (for example, with a thickness in a range of about 1 nm to 5 nm) may be formed by deposition on a surface of the stack of semiconductor layers patterned in the form of nanowire/nanosheet on the substrate 1001. Here, the etch stop layer 1019′ may also include an oxide and thus is shown as a thin layer integrated with the STI 1019.

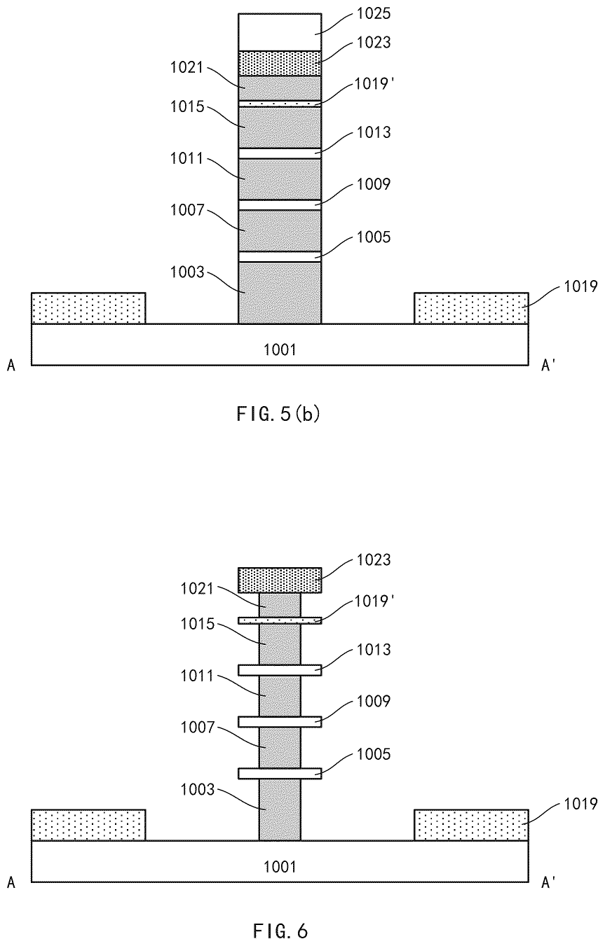

As described above, the gate defining layers 1007, 1011 and 1015 are located on the upper and lower sides of the nanowire/nanosheet defining layers 1009 and 1013. In order to form the GAA configuration, a further gate defining layer may be formed on the left and right sides under an orientation shown in FIG. 4(b). For example, as shown in FIGS. 5(a) and 5(b), a gate defining layer 1021 may be formed on the STI 1019 and the etch stop layer 1019′. For example, the gate defining layer 1021 may be formed by depositing a material that is substantially the same as or similar to that of the previous gate defining layers 1007, 1011 and 1015 (thereby having substantially the same or similar etching selectivity for processing together), and performing a planarization processing such as CMP on the deposited material. In this example, the gate defining layer 1021 may include SiGe with a Ge atom percentage that is substantially the same as or similar to that of the gate defining layers 1007, 1011 and 1015.

A hard mask layer 1023 may be formed on the gate defining layer 1021 by, for example, deposition to facilitate patterning. For example, the hard mask layer 1023 may include silicon carbide with a thickness in a range of about 100 nm to 250 nm.

The gate defining layers 1021 (as well as 1007, 1011 and 1015) may be patterned as a dummy gate that extends in a direction (which may be referred to as a “second direction”, for example, the vertical direction within the paper plane in FIG. 5(a), and the direction perpendicular to the paper plane in FIG. 5(b)) that intersects with such as perpendicular to an extension direction (which may be referred to as the “first direction”, for example, the horizontal direction within the paper planes in FIGS. 5(a) and 5(b)) of the preparatory nanowire/nanosheet. For example, a photoresist 1025 may be formed on the hard mask layer 1023 and patterned as a strip extending in the second direction through photolithography. Then, selective etching such as RIE may be performed on the layers between STIs 1019 on the substrate 1001 sequentially, by using the photoresist 1025 and the hard mask layer 1023 as masks. The etching may be stopped at the substrate 1001. As a result, the nanowire/nanosheet defining layers 1009 and 1013 are formed as nanowires or nanosheets that may subsequently be used to provide channels (hereinafter, the nanowire/nanosheet defining layers 1009 and 1013 are referred to as nanowires/nanosheets 1009 and 1013), and are surrounded by the gate defining layers 1007, 1011, 1015, and 1021 (collectively referred to as “dummy gate”). The nanowires/nanosheets 1009 and 1013 may be self-aligned with the dummy gate. Afterwards, the photoresist 1025 may be removed.

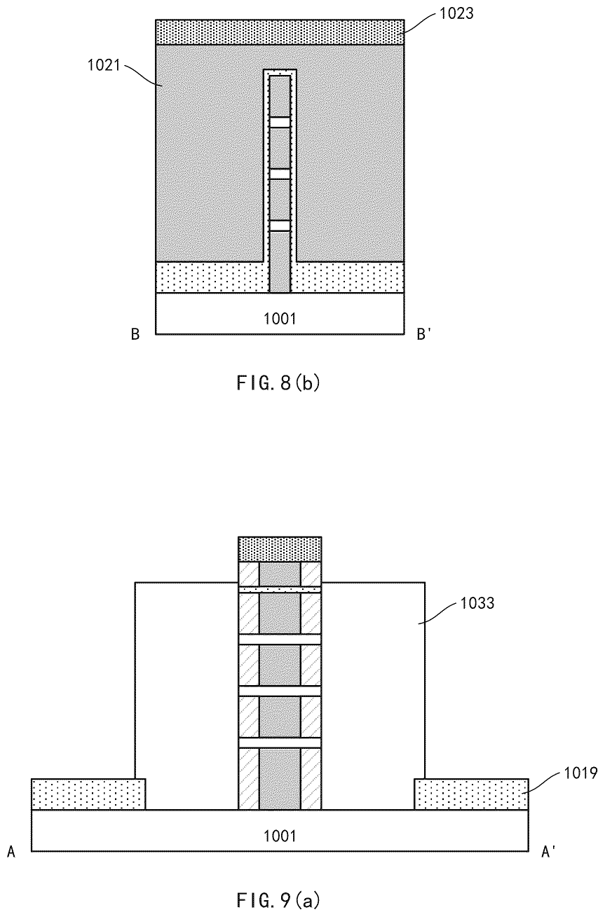

In addition, as shown in FIG. 5(b), surfaces of the substrate 1001 are exposed on both sides of the dummy gate. These exposed surfaces may aid in the subsequent growth of the source/drain layer. In addition, on opposite sides of the isolation portion defining layer 1003 in the second direction (a direction perpendicular to the paper plane in the figure), the STI 1019 may adjoin the isolation portion defining layer 1003 and may extend by self-aligning to the dummy gate (see FIG. 8(b)).

Considering the definition of the gate space and the isolation between the gate and the source/drain, a spacer may be formed on the sidewall of the dummy gate. In order to ensure that the gate lengths above and below each of the nanowires/nanosheets 1009 and 1013 are identical, the self-alignment technology may be used to form the spacer. For example, as shown in FIG. 6, the gate defining layers 1007, 1011, 1015, and 1021 (in this example, SiGe) may be selectively etched relative to the nanowires/nanosheets 1009 and 1013 (in this example, Si), so that sidewalls of the gate defining layers 1007, 1011, 1015 and 1021 are recessed inward by a certain depth relative to the sidewall of the hard mask layer 1023 or the sidewalls of the nanowires/nanosheets 1009 and 1013. Preferably, recess depths of the gate defining layers 1007, 1011, 1015 and 1021 are substantially identical, and recess depths on the left side and recess depths on the right side are substantially identical. For example, atomic layer etching (ALE) may be used to achieve good etching control. In this example, the isolation portion defining layer 1003 may also include SiGe, so it may also be recessed by substantially the same depth. Therefore, the corresponding sidewalls of the etched gate defining layers 1007, 1011, 1015 and 1021 (as well as the isolation portion defining layer 1003) may be substantially coplanar.

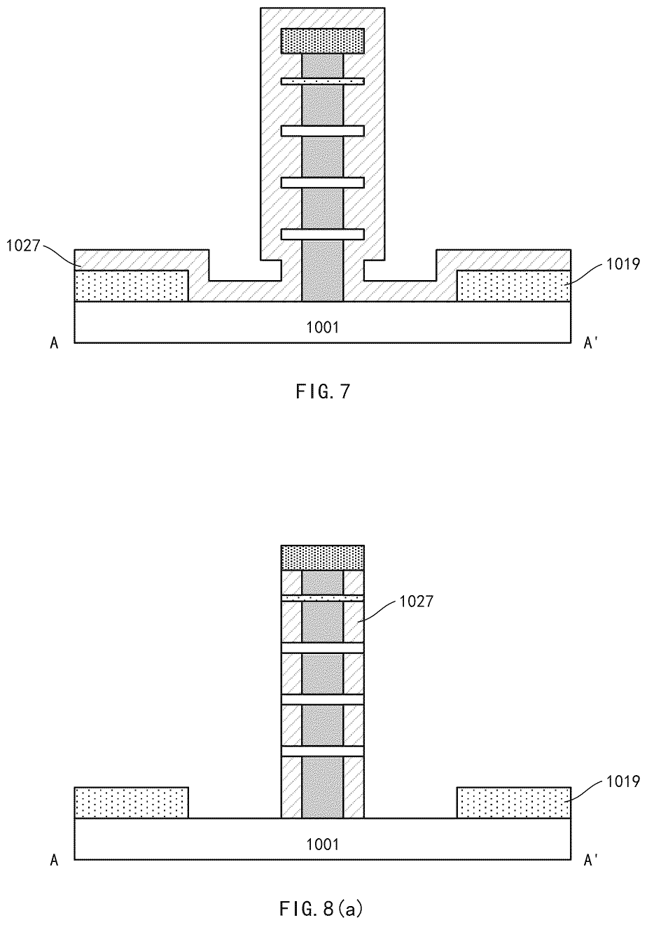

A spacer may be formed in the formed recess. As shown in FIG. 7, a dielectric material layer 1027 with a certain thickness may be formed on the substrate 1001 by deposition, for example. The thickness of the deposited dielectric material layer 1027, for example, in a range of about 3 nm to 15 nm, is sufficient to fill the above-described recess. Afterwards, as shown in FIGS. 8(a) and 8(b), a lateral extension part of the dielectric material layer 1027 may be removed and a vertical extension part (including the part below the hard mask layer 1023) of the dielectric material layer 1027 may be left by, for example, RIE in the vertical direction, so as to form a spacer 1027. A sidewall of the spacer 1027 may be substantially coplanar with the sidewall of the hard mask layer 1023 (as well as the sidewalls of the nanowires/nanosheets 1009 and 1013).

According to an embodiment of the present disclosure, the spacer 1027 may facilitate crystal growth. Unlike the dielectric material used for an existing spacer such as an oxide (silicon oxide), a nitride (silicon nitride), a nitrogen oxide (silicon oxynitride), etc., the dielectric material used for the spacer 1027 here may have substantially the same crystal structure as the nanowires/nanosheets 1009 and 1013, and the recess may be filled with the dielectric material by epitaxial growth or deposition followed by RIE. The spacer 1027 may form a eutectic along with the nanowires/nanosheets 1009 and 1013, or the subsequently formed source/drain layer. For example, the spacer 1027 may include a single crystal dielectric material that may have appropriate dielectric properties and may match the lattices of the nanowires/nanosheets 1009 and 1013, such as an oxide or a nitride of: strontium (Sr), titanium (Ti), lanthanum (La), aluminum (Al), neodymium (Nd), lutetium (Lu), gadolinium (Gd), or a combination thereof. For example, the spacer 1027 may include at least one of SrTiO₃, LaAlO₃, NdAlO₃, GdAlO₃, etc. Alternatively, the spacer may also include a semiconductor material, and a bandgap width of the semiconductor material is greater than or equal to bandgap widths of the nanowires/nanosheets 1009 and 1013 or a bandgap width of the subsequently formed source/drain layer, such as undoped silicon. According to embodiments, a difference between the lattice constant of the spacer 1027 without strain and the lattice constants of the nanowires/nanosheets 1009 and 1013 without strain is within ±2%.

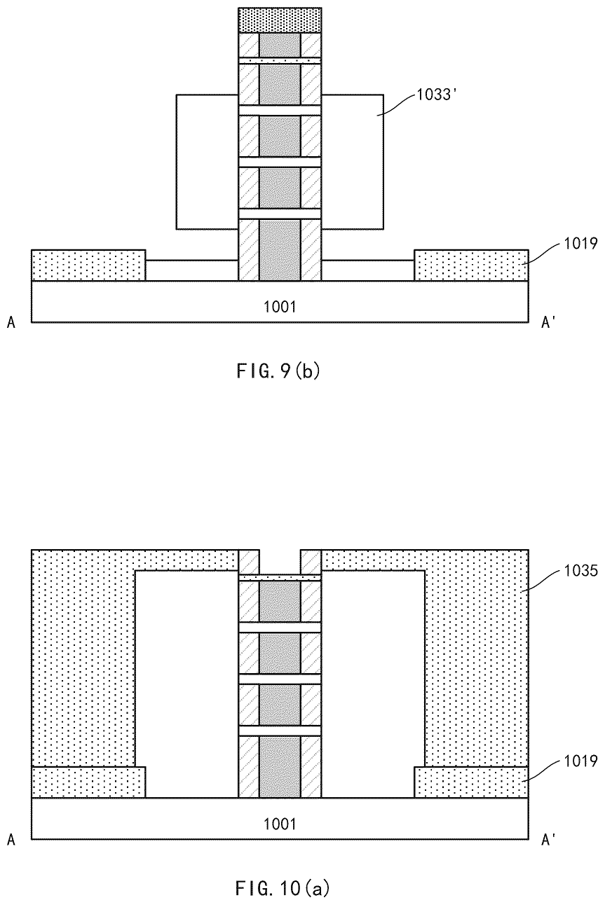

As shown in FIGS. 8(a) and 8(b), in the first direction (the horizontal direction within the paper plane in FIG. 8(a)), the sidewall of each nanowire/nanosheet is exposed to the outside (and may be substantially coplanar with the sidewall of the hard mask layer). As shown in FIGS. 9(a) and 9(b), the source/drain layer 1033 may be formed through selective epitaxial growth, by using the exposed sidewalls of the nanowires/nanosheets (as well as the exposed surface of the substrate 1001) as seeds. The source/drain layer 1033 may be formed to adjoin the exposed sidewalls of all nanowires/nanosheets. The source/drain layer 1033 may include various suitable semiconductor materials. To enhance device performance, the source/drain layer 1033 may include a semiconductor material with a lattice constant different from that of the nanowire/nanosheet to apply a stress to the nanowire/nanosheet in which the channel region will be formed. For example, for an n-type device, the source/drain layer 1033 may include Si: C (with a C atom percentage in a range of about 0.1% to 3%) to apply a tensile stress. For a p-type device, the source/drain layer 1033 may include SiGe (with a Ge atom percentage in a range of about 20% to 80%) to apply a compressive stress. In addition, the source/drain layer 1033 may be doped to a desired conductivity type (n-type doping for the n-type device and p-type doping for the p-type device), by in situ doping or ion implantation.

In an embodiment shown in FIG. 9(a), the source/drain layer grown from the sidewall of the nanowire/nanosheet adjoins the source/drain layer grown from the surface of the substrate 1001. This helps to dissipate heat or enhance the stress in the channel, thereby improving the device performance. In addition, in an embodiment shown in FIG. 9(b), the source/drain layer 1033′ grown from the sidewall of the nanowire/nanosheet is separated from the source/drain layer grown from the surface of the substrate 1001. In the following, the case shown in FIG. 9(a) will be mainly used as an example for description

Next, the gate replacement process may be performed.

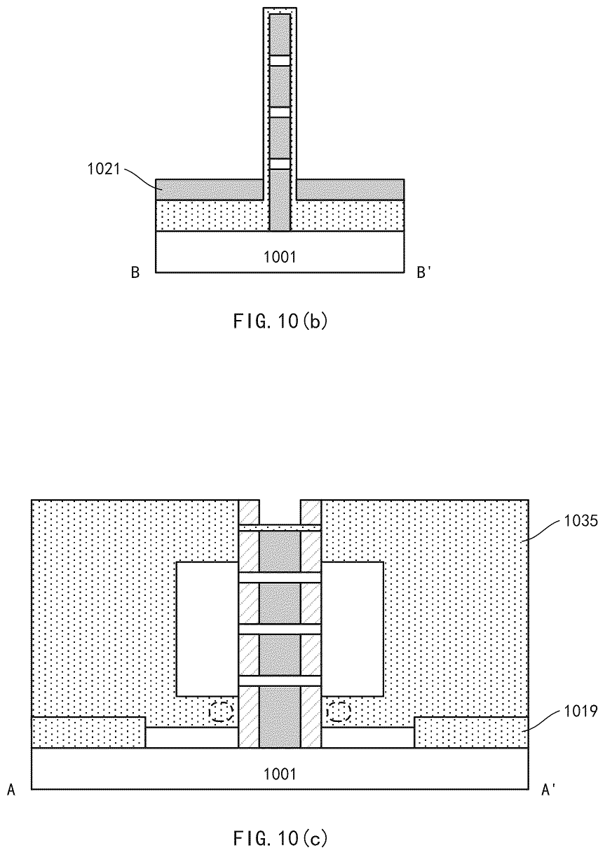

As shown in FIGS. 10(a) and 10(b), an interlayer dielectric layer 1035 may be formed on the substrate 1001. For example, the interlayer dielectric layer 1035 may be formed by depositing an oxide, performing a planarization processing such as CMP on the deposited oxide, and etching back the planarized oxide. The interlayer dielectric layer 1035 may expose the hard mask layer 1023, and cover the source/drain layer 1033. Afterwards, the hard mask layer 1023 may be removed by selective etching to expose the gate defining layer 1021.

In addition, in the case shown in FIG. 9(b) above, the interlayer dielectric layer 1035 may also be filled between the source/drain layer and the substrate, as shown in FIG. 10(c), which helps to reduce the leakage current. In addition, the filling process may be controlled, so that the interlayer dielectric layer 1035 may create holes between the source/drain layer and the substrate, as shown by the dashed lines in FIG. 10(c), which helps to reduce the capacitance between the source/drain layer and the substrate.

To perform the gate replacement process, the dummy gate, i.e. all gate defining layers, should be removed and replaced with the gate stack. Here, considering the formation of the isolation portion below the lowest gate defining layer 1007, the isolation portion defining layer 1003 may be processed, and specifically, may be replaced with the isolation portion. For this purpose, a processing channel to the isolation portion defining layer 1003 may be formed.

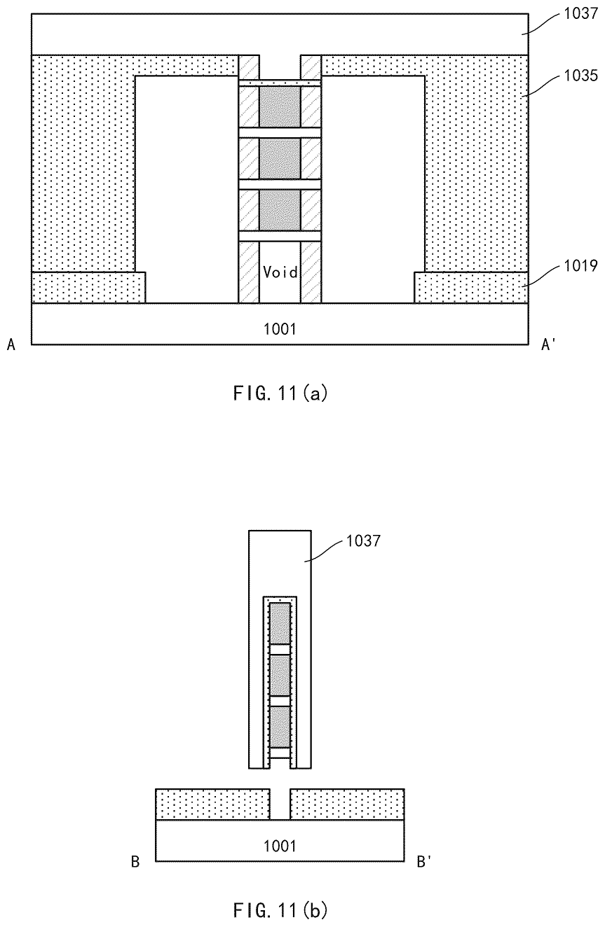

For example, by selective etching, the height of the gate defining layer 1021 may be reduced to a point where the top surface of the gate defining layer 1021 is lower than the top surface of the isolation portion defining layer 1003, but still maintains a certain thickness, so that the subsequently formed mask layer (see 1037 in FIGS. 11(a) and 11(b)) may shield all the gate defining layers 1007, 1011 and 1015 above the top surface of the isolation portion defining layer 1003, and expose the isolation portion defining layer 1003. For example, ALE may be used to better control the etching depth. Here, due to the presence of the etch stop layer 1019′, other gate defining layers 1007, 1011 and 1015 may be unaffected.

Next, as shown in FIGS. 11(a) and 11(b), a mask layer, such as a photoresist 1037, may be formed on the gate defining layer 1021. By photolithography, the photoresist 1037 may be patterned as a strip extending in the extension direction of the nanowire/nanosheet, and may shield the outer surfaces of the nanowire/nanosheet and gate defining layers 1007, 1011 and 1015 (with the etch stop layer 1019′ sandwiched therebetween). Due to the presence of the gate defining layer 1021, a part of the surface of the isolation portion defining layer 1003 is not shielded by the photoresist 1037. Afterwards, selective etching may be used to sequentially remove the gate defining layer 1021, a part of the etch stop layer 1019′ exposed due to the removal of the gate defining layer 1021, and the isolation portion defining layer 1003 exposed due to the removal of the part of the etch stop layer 1019′. Therefore, a void is formed below the etch stop layer 1005. As the isolation portion defining layer 1003 is defined by the same hard mask layer as the upper nanowires/nanosheets and gate defining layers, the isolation portion defining layer 1003 is aligned with the upper nanowires/nanosheets and gate defining layers in the vertical direction. Therefore, the void caused by the removal of the isolation portion defining layer 1003 may be self-aligned with the upper nanowires/nanosheets and gate defining layers. Afterwards, the photoresist 1037 may be removed.

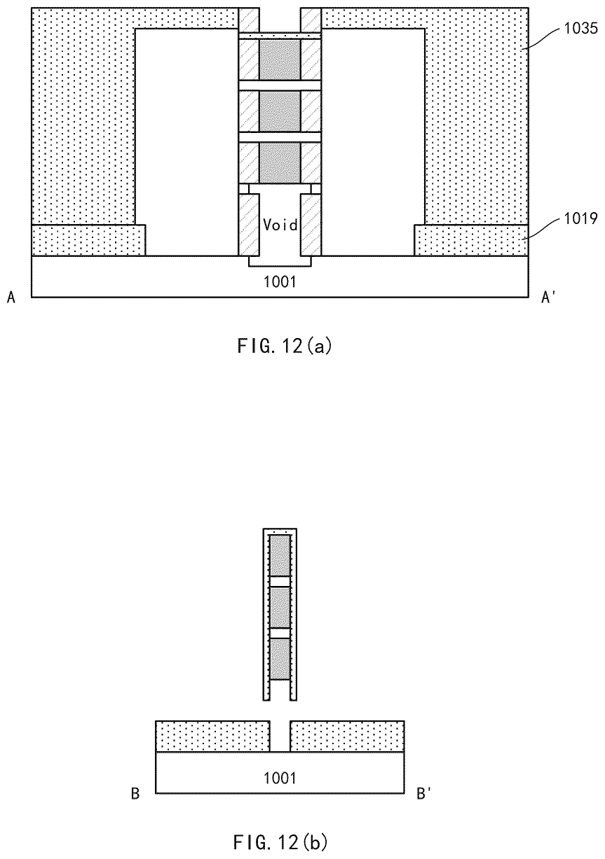

In this example, the etch stop layer 1005 may also include a semiconductor material and is connected between opposite source/drain layers, which may lead to a leakage path. For this purpose, as shown in FIGS. 12(a) and 12(b), the etch stop layer 1005 may be cut between opposite source/drain layers by selective etching, such as wet etching using TMAH solution. The end of the etch stop layer 1005 may be left to avoid affecting the source/drain layers on both sides. In an aspect, the end of the left etch stop layer 1005 may not extend to the inner side of the spacer to avoid being in contact with the gate defining layer (subsequently replaced by the gate stack) on the inner side of the spacer. That is, the inner sidewall of the left etch stop layer 1005 may be recessed relative to the inner sidewall of the spacer. As etching is started from the middle, the opposite ends of the left etch stop layer 1005 may be substantially symmetrical. In addition, in this example, both the etch stop layer 1005 and the substrate 1001 include silicon, and thus a part of the substrate 1001 may also be etched out. Therefore, the void between the lowest gate defining layer 1007 and the substrate 1001 may be enlarged, but may still maintain substantial alignment with the upper nanowires/nanosheets and gate defining layers.

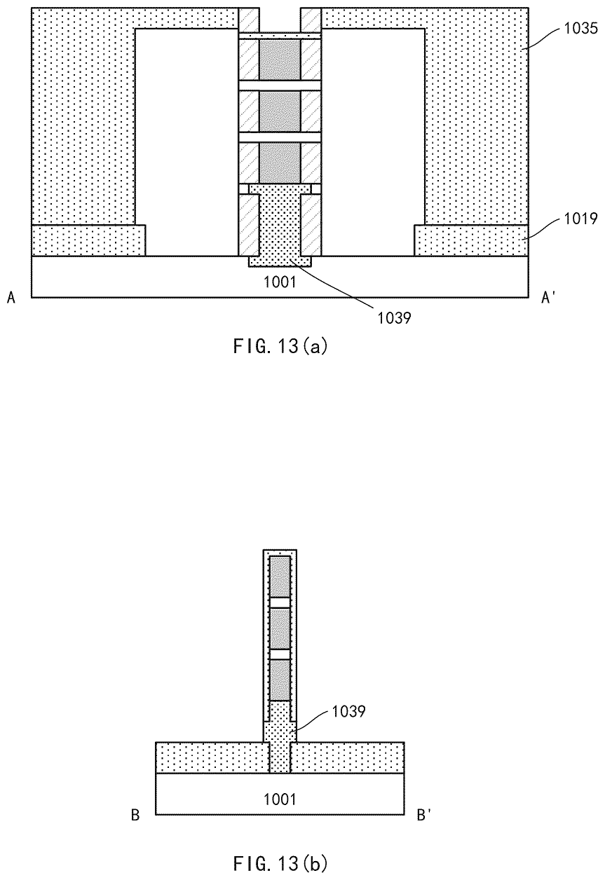

As shown in FIGS. 13(a) and 13(b), a dielectric material, such as a low k dielectric material, may be filled in the void thus formed to form an isolation portion 1039. The material of the isolation portion 1039, such as nitrogen oxide (e.g. silicon oxynitride), may have etching selectivity relative to the STI 1019. For example, the isolation portion 1039 may be formed by depositing sufficient nitrogen oxide on the substrate 1001 and etching back the deposited nitrogen oxide by RIE. The isolation portion 1039 thus formed may be self-aligned with the upper nanowires/nanosheets and gate defining layers.

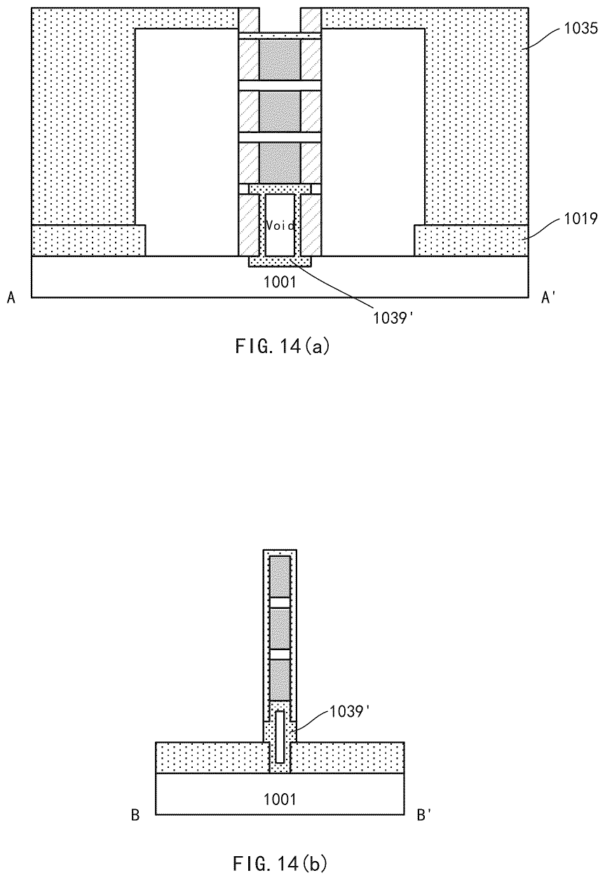

According to another embodiment, as shown in FIGS. 14(a) and 14(b), when depositing the dielectric material, the isolation portion 1039′ may form a hollow structure due to the confined space of the void described above. In this case, the dielectric constant of the isolation portion 1039′ may be further reduced.

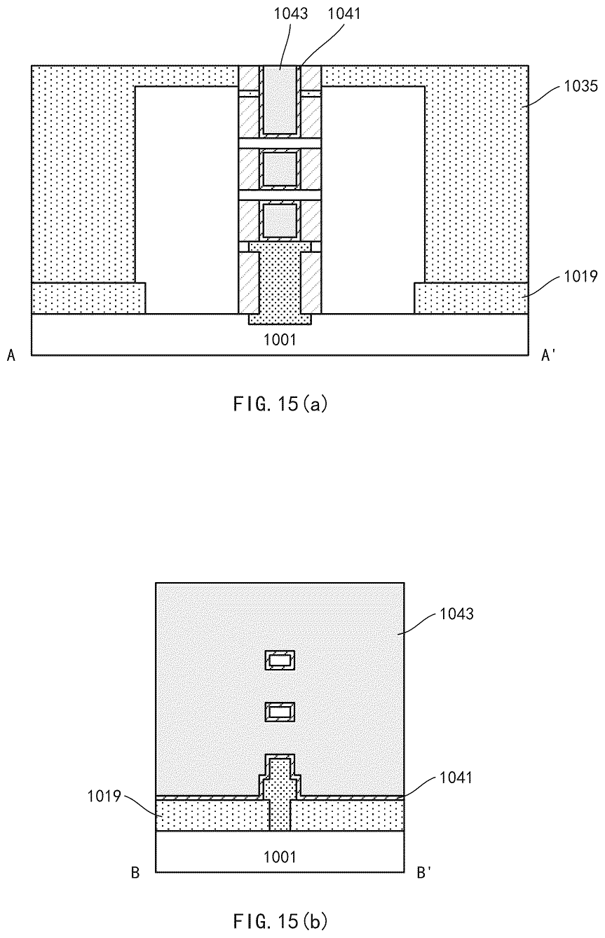

Next, as shown in FIGS. 15(a) and 15(b), the thin etch stop layer 1019′ may be removed by selective etching to expose the gate defining layer. Furthermore, the gate defining layer may be removed by selective etching. Therefore, a gate trench (corresponding to the space originally occupied by each gate defining layer) is formed on an inner side of the spacer 1027 and above the STI 1019 and the isolation portion 1039. In the gate trench thus formed, a gate dielectric layer 1041 and a gate electrode 1043 may be sequentially formed to obtain the resultant gate stack. For example, the gate dielectric layer 1041 may include a high k gate dielectric such as HfO₂, with a thickness in a range of about 2 nm to 10 nm. The gate electrode 1043 may include a work function adjustment layer such as TiN, TiAlN, TaN, etc., as well as a gate conductor layer such as W, Co, Ru, etc. Before forming the high k gate dielectric, an interface layer may further be formed, such as an oxide formed through an oxidation process or deposition such as atomic layer deposition (ALD), with a thickness in a range of about 0.3 nm to 2 nm.

As shown in FIGS. 15(a) and 15(b), the nanowire/nanosheet device according to embodiments may include the nanowires/nanosheets 1009 and 1013 (which may be fewer or more in number) spaced apart from the substrate 1001, as well as the gate stack surrounding the nanowires/nanosheets 1009 and 1013. The gate stack includes the gate dielectric layer 1041 and the gate electrode 1043.

The spacer 1027 is formed on the sidewall of the gate stack. Inner sidewalls of the spacer 1027 may be substantially coplanar in the vertical direction, so as to provide the same gate length. In addition, the outer sidewalls of the spacer 1027 may also be coplanar in the vertical direction and may be coplanar with the sidewalls of the nanowires/nanosheets 1009 and 1013. As described above, the spacer 1027 may have substantially the same crystal structure as the nanowires/nanosheets 1009 and 1013 to facilitate the growth of high-quality source/drain layers.

The nanowire/nanosheet device may further include an isolation portion 1039. As described above, the isolation portion 1039 may be self-aligned with the gate stack or nanosheets 1009 and 1013, so that at least a part of the sidewalls of the isolation portion 1039 may be aligned in the vertical direction with the corresponding sidewalls of the upper gate stack. For example, as shown in FIG. 15(a), at least middle parts of the opposite sidewalls of the isolation portion 1039 in the extension direction of the nanowire/nanosheet (the horizontal direction within the paper plane in the figure) may be aligned in the vertical direction with the corresponding sidewalls of the gate stack. In addition, as shown in FIG. 15(b), at least upper parts of the opposite sidewalls of the isolation portion 1039 in the extension direction of the gate (the horizontal direction within the paper plane in the figure) may be aligned in the vertical direction with the corresponding sidewalls of the gate stack (at the interface between the gate stack and the nanowire/nanosheet). The parts of the sidewalls of the isolation portion 1039 that are not coplanar with the corresponding sidewalls of the gate stack (if they exist; these parts are caused by the process, these parts may not exist due to different processes) may also maintain substantial conformal extension with the corresponding sidewalls of the gate stack.

The spacer 1027 may also be formed on the sidewall of the isolation portion 1039. An upper part of the isolation portion 1039 may be located between the upper and lower parts of the spacer 1027, but does not extend beyond the outer sidewall of the spacer 1027.

As described above, the isolation portion 1039 is aligned with the nanowires/nanosheets 1009 and 1013 in the vertical direction. In addition, as shown in FIG. 15(b), the isolation portion 1039 adjoins the STIs 1019 on opposite sides of the gate in the extension direction (the horizontal direction within the paper plane in FIG. 15(b)), so that the gate stack is isolated from the substrate through the isolation portion 1029 and the STIs 1019. A part of the STIs 1019 below the gate stack may also be self-aligned with the gate stack, as such part of the STIs 1019 may be patterned to be left below the dummy gate (subsequently replaced by the gate stack) by the dummy gate patterning process described with reference to FIGS. 5(a) and 5(b) above.

In above embodiments, the entire spacer 1027 may substantially be used as a seed crystal layer for the growth of the source/drain layer. However, the present disclosure is not limited to this. For example, only a part of the spacer (especially the part of the spacer adjacent to at least one of the nanowires/nanosheets 1009 and 1013) may have a structure substantially identical to that of the nanowires/nanosheets 1009 and 1013.

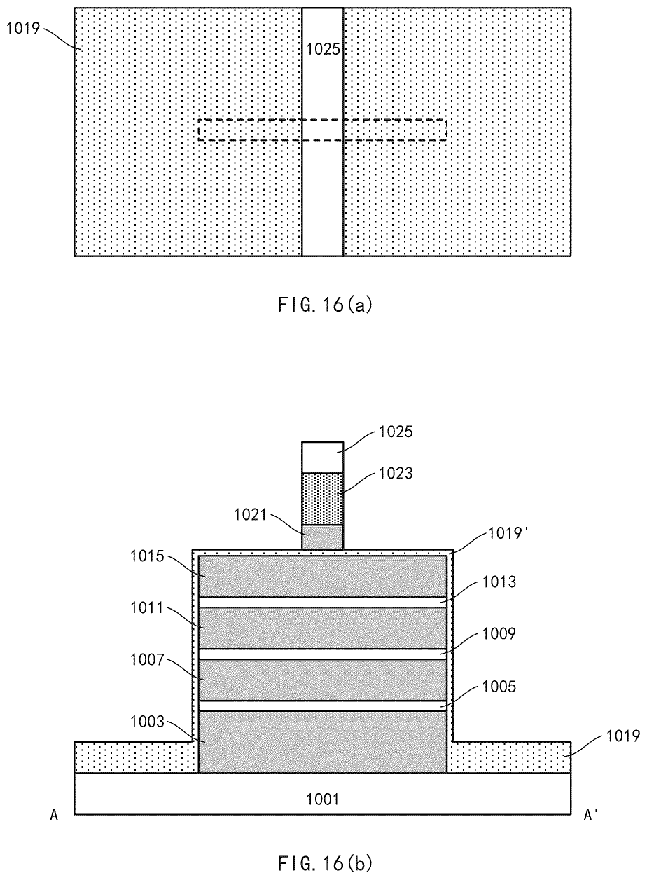

FIGS. 16(a) to 21 show schematic diagrams of some stages in a process of manufacturing a nanowire/nanosheet device according to another embodiment of the present disclosure.

In above embodiments, after patterning the gate defining layer 1021, the photoresist 1025 may also be used as the etching mask to pattern the gate defining layers 1007, 1011 and 1015 below, so that they form the dummy gate together. In this embodiment, the spacer may be formed in stages. The advantages of forming the spacer in stages will be described in detail below in conjunction with subsequent processes.

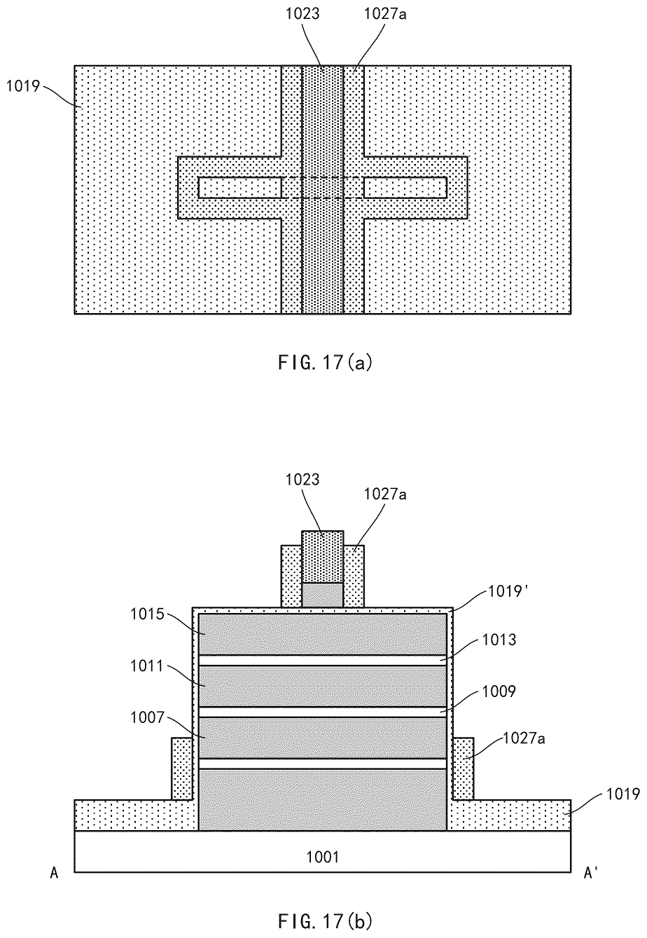

For example, as shown in FIGS. 16(a) and 16(b), the gate defining layer 1021 (and the hard mask layer 1023) are patterned by using the strip-shaped photoresist 1025. Then, as shown in FIGS. 17(a) and 17(b), a first sub-spacer 1027a may be formed on the sidewall of the gate defining layer 1021 that is patterned as a strip extending in the second direction. The formation method of the first sub-spacer 1027a may be the same as the formation method of the above-described spacer 1027, and the first sub-spacer 1027a may also include a nitride here. Here, the etching back depth in the spacer formation process may be controlled to form the first sub-spacer 1027a on the sidewall of the stack of semiconductor layers, which helps guide the growth of the source/drain layer.

After forming the first sub-spacer 1027a, similar to the description with reference to FIGS. 5(a) to 8(b), a second sub-spacer may be formed on the sidewalls of the gate defining layers 1007, 1011 and 1015.

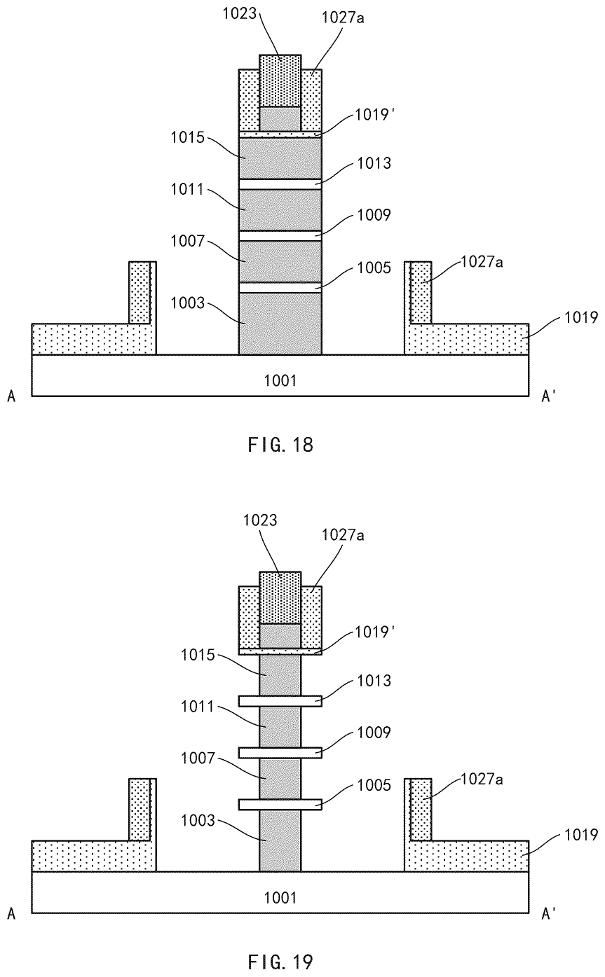

For example, as shown in FIG. 18, by using the hard mask layer 1023 and the first sub-spacer 1027a as etching masks, selective etching such as RIE may be performed on the etch stop layer 1019′ and the layers in the stack of semiconductor layers sequentially. The etching may be stopped at the substrate 1001. As a result, the nanowire/nanosheet defining layers 1009 and 1013 are formed as nanowires/nanosheets 1009 and 1013 and are surrounded by the gate defining layers 1007, 1011, 1015 and 1021 (forming the “dummy gate” together). The nanowires/nanosheets 1009 and 1013 may be self-aligned with the dummy gate.

Next, as shown in FIG. 19, the gate defining layers 1007, 1011 and 1015 (in this example, SiGe) may be selectively etched relative to the nanowires/nanosheets 1009 and 1013 (in this example, Si), so that sidewalls of the gate defining layers 1007, 1011 and 1015 are recessed inward by a certain depth in the lateral direction relative to the sidewalls of the nanowires/nanosheets 1009 and 1013. Preferably, the recess depths of the gate defining layers 1007, 1011 and 1015 are substantially identical, and the recess depths on the left side and the recess depths on the right side are substantially identical (and may be substantially equal to the thickness of the first spacer 1027). For example, ALE may be used to achieve good etching control. In this example, the isolation portion defining layer 1003 may also include SiGe, so it may also be recessed by substantially the same depth. Therefore, the corresponding sidewalls of the etched gate defining layers 1007, 1011 and 1015 (as well as the isolation portion defining layer 1003, and even the gate defining layer 1021) may be substantially coplanar.

A second sub-spacer may be formed in such formed recess. As shown in FIGS. 20(a), 20(b), and 20(c), a second sub-spacer 1027b may be formed in the recess by, for example, epitaxial growth or deposition followed by RIE. The second sub-spacer 1027b is similar to the spacer 1027 described above and may have a crystal structure substantially identical to that of the nanowires/nanosheets 1009 and 1013, and the lattice constant of the crystal structure of the second sub-spacer 1027b may be matched with the lattice constant of the crystal structure of the nanowires/nanosheets 1009 and 1013. The second sub-spacer 1027b and the first sub-spacer 1027a form the spacer together, defining the space for the gate stack. An outer sidewall of the second sub-spacer 1027b may be substantially coplanar with an outer sidewall of the first sub-spacer 1027a (as well as the sidewalls of the nanowires/nanosheets 1009 and 1013). An inner sidewall of the second sub-spacer 1027b may be substantially planarized (so as to define substantially the same gate length above and below the nanowires/nanosheets 1009 and 1013).

As shown in FIGS. 20(a) and 20(c), on opposite sides in the first direction, crystal growth surfaces (the outer sidewall of the second sub-spacer 1027′ and the sidewalls of the nanowires/nanosheets 1009 and 1013) that extend substantially continuous and have substantially consistent crystal structures may be formed, which facilitates the growth of high-quality source/drain layers.

As shown in FIG. 21, the outer sidewall of the second sub-spacer 1027b and the exposed sidewalls of the nanowires/nanosheets 1009 and 1013 (and the etch stop layer 1005) (as well as the exposed surface of the substrate 1001) may be used as seeds to form a source/drain layer 1033 by selective epitaxial growth, for example. As described above, the first sub-spacer 1027a may guide the growth of the source/drain layer 1033. Regarding the source/drain layer 1033, please refer to the above embodiments.

Due to the presence of the continuous extending and substantially consistent crystal growth surface shown in FIG. 20(c), the grown source/drain layer 1033 may have good crystal quality with almost no or fewer crystal defects such as dislocations or interfaces. In addition, good crystal quality may also help improve the stress level when applying the stress.

In addition, as shown in FIG. 20(c), except for the second sub-spacer 1027b in the middle, the first sub-spacer 1027a is on both sides in the second direction. This may limit the growth range of the source/drain layer in the second direction, thereby avoiding unnecessary connection between respective source/drain layers of devices adjacent in the second direction (to reduce unnecessary etching steps).

Next, the gate replacement process may be performed similarly, which will not be repeated here.

According to an embodiment of the present disclosure, the dummy gate may also be used to form a self-aligned isolation portion, such as shallow trench isolation (STI).

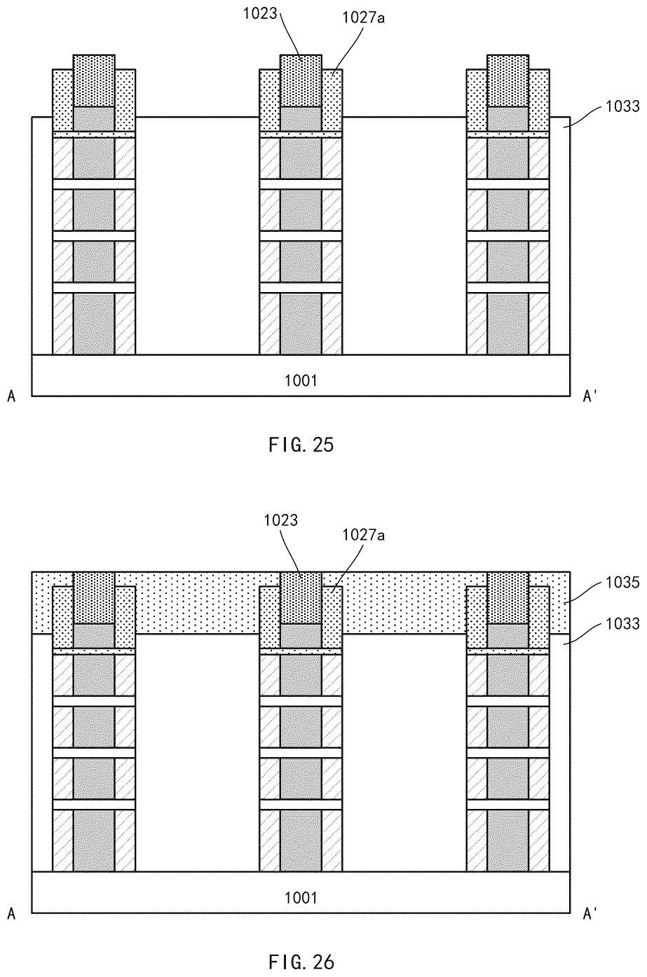

FIGS. 22(a) to 29 show schematic diagrams of some stages in a process of manufacturing a nanowire/nanosheet device according to another embodiment of the present disclosure. The following mainly describes the differences between this embodiment and the above embodiments. For other processes not described in detail, please refer to the above embodiments.

As described above in conjunction with FIGS. 1 to 4(b), a stack of semiconductor layers may be provided on the substrate 1001 and patterned as a preparatory nanowire/nanosheet. An isolation portion 1019 may be formed around the preparatory nanowire/nanosheet, and an etch stop layer 1019′ may be formed on its surface.

As shown in FIGS. 22(a) and 22(b), the dummy gate may be patterned as described above in conjunction with FIGS. 16(a) and 16(b). Here, the photoresist 1025 is patterned as a plurality of (e.g., three) strips spaced (which may be substantially equidistant) in the first direction and extending in the second direction.

Next, the process may be performed according to the above embodiments.

For example, as shown in FIGS. 23(a) to 23(d), a first sub-spacer 1027a may be formed on the sidewall of the strip-shaped gate defining layer 1021 as described above in conjunction with FIGS. 17(a) and 17(b). The first sub-spacer 1027a may also be formed on the (bottom) sidewall of the stack of semiconductor layers to guide the growth of the source/drain layer. Then, as described above in conjunction with FIGS. 18 to 20(c), a second sub-spacer 1027b may be formed, as shown in FIGS. 24(a) to 24(d). Similarly, as shown in FIG. 24(d), crystal growth surfaces (the outer sidewall of the second sub-spacer 1027b and the sidewalls of the nanowires/nanosheets 1009 and 1013) that extend substantially continuous and have substantially consistent crystal structures may be formed on opposite sides in the first direction. Afterwards, the source/drain layer 1033 may be grown as described above in combination with FIG. 21.

Here, the dummy gate may be used to fabricate the self-aligned isolation portion.

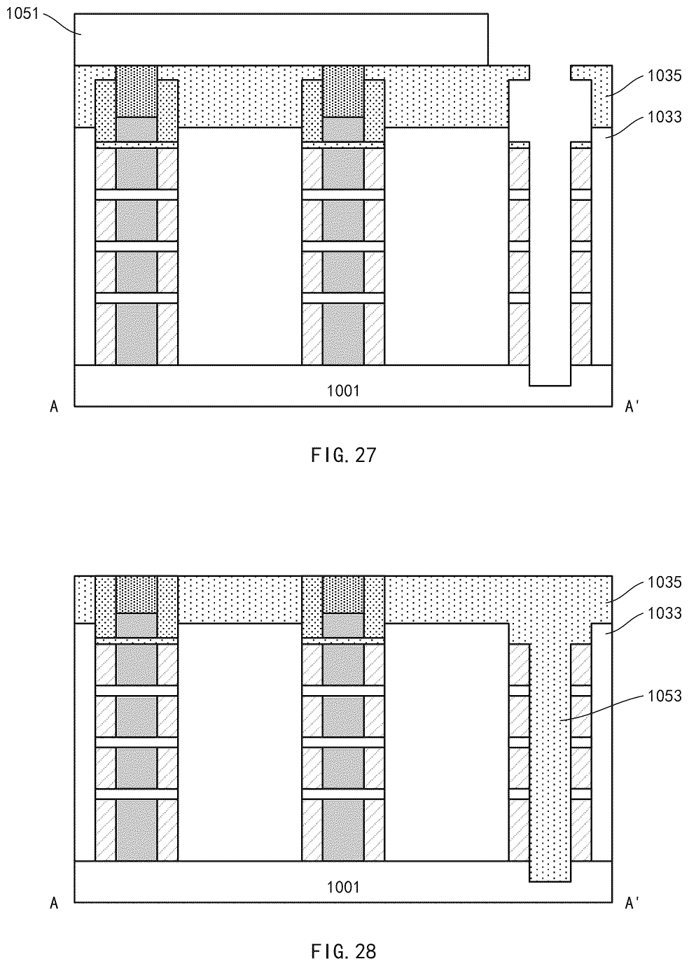

For example, as shown in FIG. 26, an interlayer dielectric layer 1035 may be formed on the substrate 1001. The interlayer dielectric layer 1035 may expose the hard mask layer 1023. As shown in FIG. 27, a photoresist 1051 may be used to shield a device region and expose a region where the isolation portion needs to be formed (in this example, a region where the rightmost dummy gate is located in FIG. 27). In the region exposed by the photoresist 1051, the hard mask layer 1023, the gate defining layers 1021, 1015, 1011 and 1017, the nanowire/nanosheets 1013 and 1019, as well as the isolation portion defining layer 1003 (as well as the etch stop layers 1019′ and 1005) may be removed by selective etching such as RIE. Here, the first sub-spacer 1027 may also be removed. Therefore, a trench corresponding to the dummy gate is formed. Afterwards, the photoresist 1051 may be removed. As shown in FIG. 28, the trench thus formed may be filled with a dielectric such as an oxide to form an isolation portion 1053. Here, as both the isolation portion 1053 and the interlayer dielectric layer 1035 include oxides, an interface between the isolation portion 1053 and the interlayer dielectric layer 1035 is not shown. However, as the isolation portion 1053 and the interlayer dielectric layer 1035 are formed separately, it is possible to observe the interface between the isolation portion 1053 and the interlayer dielectric layer 1035. Alternatively, the isolation portion 1053 has a second sub-spacer 1027′, a nanowire/nanosheet residue, etc. on the sidewall, so as to define the sidewall of the isolation portion 1053. Alternatively, even if the second sub-spacer 1027′ and the nanowire/nanosheet residue on the sidewall of the trench are difficult to observe because they are almost removed due to etching control in the process of forming the trench, the sidewall of the isolation portion 1053 may still be defined due to the presence of the source/drain layers on both sides of the isolation portion 1053.

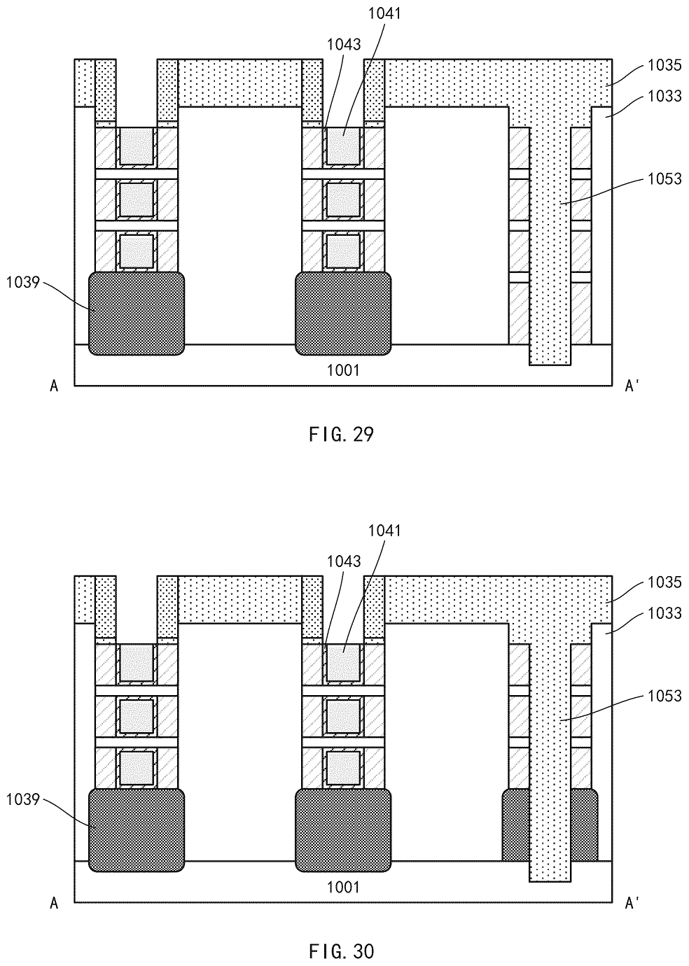

Next, the process may be performed according to the above embodiments, such as the gate replacement process. Therefore, the nanowire/nanosheet device shown in FIG. 29 may be obtained.

In this example, the isolation portion 1053 is formed, and then the gate replacement process is performed. However, the present disclosure is not limited to this. For example, the gate replacement process may be performed as described in the above embodiment, and then the isolation portion 1053 may be formed (except that the gate defining layer is replaced with the gate stack when etching the trench). Therefore, the nanowire/nanosheet device shown in FIG. 30 may be obtained.

In the above embodiment, a single material layer (such as an oxide) is used as an example to describe the spacer. However, the present disclosure is not limited to this. For example, the spacer may include a stack of multiple layers (such as a nitride layer and an oxide layer). For example, the layers in the stack may be sequentially deposited by ALD.

The nanowire/nanosheet device according to embodiments of the present disclosure may be applied to various electronic apparatuses. For example, an integrated circuit (IC) may be formed based on such nanowire/nanosheet devices, and an electronic apparatus may be constructed in this way. Therefore, the present disclosure further provides an electronic apparatus including the nanowire/nanosheet device described above. The electronic apparatus may further include components such as a display screen cooperating with the integrated circuit and a wireless transceiver cooperating with the integrated circuit. The electronic apparatus may include, for example, a smart phone, a computer, a tablet computer, a wearable intelligence apparatus, an artificial intelligence apparatus, and a mobile power supply.

According to embodiments of the present disclosure, a method of manufacturing a system on chip (SoC) is further provided. This method may include the above-described method. Specifically, a variety of devices may be integrated on the chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A nanowire/nanosheet device, comprising:
a substrate;
a nanowire/nanosheet spaced apart from a surface of the substrate and extending in a first direction;
source/drain layers located at opposite ends of the nanowire/nanosheet in the first direction and adjoining the nanowire/nanosheet;
a gate stack extending in a second direction to surround the nanowire/nanosheet, wherein the second direction intersects with the first direction; and
a spacer provided on a sidewall of the gate stack,
wherein in at least a part of a region of the spacer adjacent to the nanowire/nanosheet, the spacer has a crystal structure substantially identical to a crystal structure of the nanowire/nanosheet.

2. The nanowire/nanosheet device according to claim 1, wherein a lattice constant of the spacer in the at least the part of the region is matched with a lattice constant of the nanowire/nanosheet.

3. The nanowire/nanosheet device according to claim 2, wherein a difference between a lattice constant of the spacer in the at least the part of the region without strain and a lattice constant of the nanowire/nanosheet without strain is less than ±2%.

4. The nanowire/nanosheet device according to claim 1, wherein the spacer forms a eutectic with the nanowire/nanosheet or the source/drain layer.

5. The nanowire/nanosheet device according to claim 1, wherein the spacer comprises a dielectric material.

6. The nanowire/nanosheet device according to claim 5, wherein in the at least the part of the region, the spacer comprises an oxide or a nitride of: strontium (Sr), titanium (Ti), lanthanum (La), aluminum (Al), neodymium (Nd), lutetium (Lu), gadolinium (Gd), or a combination thereof.

7. The nanowire/nanosheet device according to claim 6, wherein in the at least the part of the region, the spacer comprises at least one of SrTiO₃, LaAlO₃, NdAlO₃, or GdAlO₃.

8. The nanowire/nanosheet device according to claim 5, wherein the dielectric material is a low k material.

9. The nanowire/nanosheet device according to claim 1, wherein the spacer comprises a semiconductor material, and a bandgap width of the semiconductor material is greater than or equal to a bandgap width of the nanowire/nanosheet or a bandgap width of the source/drain layer.

10. The nanowire/nanosheet device according to claim 9, wherein the semiconductor material comprises undoped silicon or low doped silicon.

11. The nanowire/nanosheet device according to claim 1, wherein the source/drain layer has fewer growth defects than a source/drain layer grown solely by using an end of the nanowire/nanosheet in the first direction as a seed.

12. The nanowire/nanosheet device according to claim 11, wherein the source/drain layer substantially does not have a growth defect.

13. The nanowire/nanosheet device according to claim 1, wherein a plurality of nanowires/nanosheets are provided, the plurality of nanowires/nanosheets extend substantially parallel to each other in the first direction and are substantially aligned in a vertical direction, and
wherein the source/drain layer has a substantially consistent and continuous crystal surface between at least one pair of adjacent nanowires/nanosheets among the plurality of nanowires/nanosheets.

14. The nanowire/nanosheet device according to claim 13, wherein a crystal structure of the source/drain layer is represented as a crystal grown from a vertically continuous extending and substantially consistent crystal surface between the plurality of nanowires/nanosheets.

15. The nanowire/nanosheet device according to claim 1, further comprising:
an isolation portion located between the gate stack and the substrate,
wherein the isolation portion is self-aligned with the gate stack.

16. The nanowire/nanosheet device according to claim 15, further comprising:
a further isolation portion provided on a side of at least one of the source/drain layers away from the nanowire/nanosheet in the first direction,
wherein a bottom surface of the further isolation portion is lower than a top surface of the isolation portion, and the further isolation portion extends in the second direction.

17. The nanowire/nanosheet device according to claim 16, further comprising:
a further spacer provided on a sidewall of the further isolation portion.

18. The nanowire/nanosheet device according to claim 17, wherein the spacer comprises a first part above the nanowire/nanosheet and a second part below the nanowire/nanosheet, and the further spacer comprises a first part substantially at a same height as the first part of the spacer and a second part substantially at a same height as the second part of the spacer.

19. The nanowire/nanosheet device according to claim 18, further comprising:
a nanowire/nanosheet residue located between the first part and the second part of the further spacer and adjoining the at least one source/drain layer.

20. The nanowire/nanosheet device according to claim 19, wherein the nanowire/nanosheet residue is substantially coplanar with the nanowire/nanosheet.

21. The nanowire/nanosheet device according to claim 1, wherein the spacer comprises a stack of multiple layers.

22. The nanowire/nanosheet device according to claim 1, wherein a sidewall of the spacer facing the gate stack above the nanowire/nanosheet is substantially coplanar with a sidewall of the spacer facing the gate stack below the nanowire/nanosheet.

23. A method of manufacturing a nanowire/nanosheet device, comprising:
providing, on a substrate, a nanowire/nanosheet spaced apart from a surface of the substrate and extending in a first direction;
forming, on the substrate, a dummy gate extending in a second direction and surrounding the nanowire/nanosheet, wherein the second direction intersects with the first direction;
forming a spacer on a sidewall of the dummy gate, wherein the spacer has a crystal structure substantially identical to a crystal structure of the nanowire/nanosheet in at least a part of a region of the spacer adjacent to the nanowire/nanosheet; and
growing a source/drain layer by using an end of the nanowire/nanosheet in the first direction and the at least the part of the region of the spacer as seeds.

24. The method according to claim 23, wherein the spacer comprises a dielectric material.

25. The method according to claim 24, wherein in the at least the part of the region, the spacer comprises an oxide or a nitride of: strontium (Sr), titanium (Ti), lanthanum (La), aluminum (Al), neodymium (Nd), lutetium (Lu), gadolinium (Gd), or a combination thereof.

26. The method according to claim 25, wherein in the at least the part of the region, the spacer comprises at least one of SrTiO₃, LaAlO₃, NdAlO₃, or GdAlO₃.

27. The method according to claim 24, wherein the dielectric material is a low k material.

28. The method according to claim 23, wherein the spacer comprises a semiconductor material, and a bandgap width of the semiconductor material is greater than or equal to a bandgap width of the nanowire/nanosheet or a bandgap width of the source/drain layer.

29. The method according to claim 28, wherein the semiconductor material comprises undoped silicon.

30. The method according to claim 23, wherein providing the nanowire/nanosheet comprises:
forming an isolation portion defining layer on the substrate;
forming, on the isolation portion defining layer, a stack of alternatively arranged one or more gate defining layers and one or more nanowire/nanosheet defining layers;
patterning the stack and the isolation portion defining layer as a preparatory nanowire/nanosheet extending in the first direction;
forming a further gate defining layer on the substrate to cover the stack and the isolation portion defining layer;
patterning the further gate defining layer as a strip extending in the second direction; and
patterning the stack into a wire or sheet shape by using the further gate defining layer in a strip shape as a mask, wherein the nanowire/nanosheet defining layer patterned in the wire or sheet shape forms the nanowire/nanosheet.

31. The method according to claim 30, wherein forming the dummy gate comprises: selective etching the gate defining layer and the further gate defining layer, so that a sidewall of the gate defining layer and a sidewall of the further gate defining layer are inward recessed relative to a sidewall of the nanowire/nanosheet to form a recess, wherein the gate defining layer and the further gate defining layer form the dummy gate together, and
wherein forming the spacer comprises: forming the spacer in the recess.

32. The method according to claim 31,
wherein providing the nanowire/nanosheet further comprises: patterning the isolation portion defining layer by using the further gate defining layer in the strip shape as the mask,
wherein forming the dummy gate further comprises: selective etching the isolation portion defining layer, so that a sidewall of the isolation portion defining layer is inward recessed relative to the sidewall of the nanowire/nanosheet, and
wherein the method further comprises:
removing, by selective etching, the isolation portion defining layer from opposite sides of the nanowire/nanosheet in the second direction; and
filling a space caused by a removal of the isolation portion defining layer with a dielectric material, so as to form an isolation portion.

33. The method according to claim 30, wherein two strips are provided, and the method further comprises:
forming an isolation portion at one of the two strips after growing the source/drain layer, wherein the isolation portion is self-aligned with the spacer and passes through the nanowire/nanosheet.

34. An electronic apparatus, comprising the nanowire/nanosheet device according to claim 1.

35. The electronic apparatus according to claim 34, wherein the electronic apparatus comprises: a smart phone, a computer, a tablet computer, a wearable intelligence apparatus, an artificial intelligence apparatus, and/or a mobile power supply.
